(19) United States
(12) Patent Application Publication
(10) Pub. No.: US 2010/0311224 A1
(43) Pub. Date: Dec. 9, 2010

(54) MANUFACTURING METHOD OF SEMICONDUCTOR DEVICE

(75) Inventors: Tetsuya Kurosawa, Yokohama-shi (JP); Junya Sagara, Kawasaki-shi (JP); Shinya Takyu, Minamisaitama-gun (JP); Norihiro Togasaki, Kawasaki-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/782,097

(22) Filed: May 18, 2010

(30) Foreign Application Priority Data
Jun. 5, 2009 (JP) 2009-136186

(51) Int. Cl. H01L 21/78

(52) U.S. Cl. 438/462; 257/E21.599

(57) ABSTRACT

According to one embodiment, a manufacturing method of a semiconductor device includes forming a plurality of first trenches in a semiconductor substrate, forming an insulating member in the first trenches, removing a part of a portion of the insulating member, forming second trenches in the insulating member, and attaching a protection film. The semiconductor substrate has a first and a second main surface. The insulating member has an upper face located higher than the first main surface. The portion is located higher than the first main surface.

### CROSS-REFERENCE TO RELATED APPLICATIONS

This application is based upon and claims the benefit of priority from Japanese Patent Application No. 2009-136186, filed on Jun. 5, 2009; the entire contents of which are incorporated herein by reference.

### FIELD

Embodiments described herein relate generally to a manufacturing method of a semiconductor device.

### BACKGROUND

In response to demands for increasing capacities and enhancing functions of semiconductor memories, semiconductor memories in which a plurality of semiconductor chips are stacked are being developed (see, for example, JP-A2009-94432 (KOKAI)). Specifically, stacking a plurality of semiconductor chips enables to secure a memory capacity exceeding that of a single semiconductor chip. Further, stacking different types of semiconductor chips makes it easy to achieve various functions.

When manufacturing such semiconductor memories, the following approach is used. Specifically, an insulating resin is filled and processed in trenches formed in an upper face of a semiconductor wafer. Thereafter, a protection film (an adhesive sheet for example) is adhered to the upper face of the semiconductor wafer and a back side thereof is ground, thereby dividing the semiconductor wafer into a plurality of semiconductor chips. These semiconductor chips are stacked to fabricate a semiconductor device (semiconductor memory).

However, there may occur a defect in the semiconductor device due to insufficient adhesion between the adhesive sheet and the semiconductor wafer (semiconductor substrate) when the semiconductor wafer is ground.

### BRIEF DESCRIPTION OF THE DRAWINGS

FIG. 1 is a flowchart representing an example of a manufacturing procedure of a semiconductor device according to an embodiment.

FIG. 2A to FIG. 2C, FIG. 3A to FIG. 3C, and FIG. 4A to FIG. 4C are cross-sectional views representing an example of the semiconductor device manufactured by the procedure of FIG. 1.

FIG. 5 is a top view representing a semiconductor wafer 10.

FIG. 6 is a cross-sectional view representing a stacked type semiconductor package 20.

FIG. 7 is a view representing a state that a projecting portion of the insulating member 13 is smoothed.

FIG. 8A to FIG. 8C are views representing a state that a projecting portion of the insulating member 13 is smoothed.

FIG. 9A and FIG. 9B are a side view and a front view, respectively, representing a cutting tool G.

FIG. 10 is a view representing a state that the projecting portion of the insulating member 13 is smoothed using the cutting tool G.

FIG. 11A and FIG. 11B are cross-sectional views representing another example of a semiconductor device manufactured by the procedure of FIG. 1.

FIG. 12A and FIG. 12B are electron micrographs representing an example of a semiconductor device manufactured by the procedure of FIG. 1.

FIG. 13 is an electron micrograph representing an example of a semiconductor device manufactured by the procedure of FIG. 1.

FIG. 14A and FIG. 14B are electron micrographs representing an example of a semiconductor device manufactured by the procedure of FIG. 1.

FIG. 15A and FIG. 15B are electron micrographs representing an example of a semiconductor device manufactured by the procedure of FIG. 1.

### DETAILED DESCRIPTION

According to one embodiment, a manufacturing method of a semiconductor device includes forming a plurality of first trenches in a semiconductor substrate, forming an insulating member in the first trenches, removing a part of a portion of the insulating member, forming second trenches in the insulating member, and attaching a protection film. The semiconductor substrate has a first and a second main surface. The insulating member has an upper face located higher than the first main surface. The portion is located higher than the first main surface.

Hereinafter, an embodiment will be described in detail with reference to the drawings.

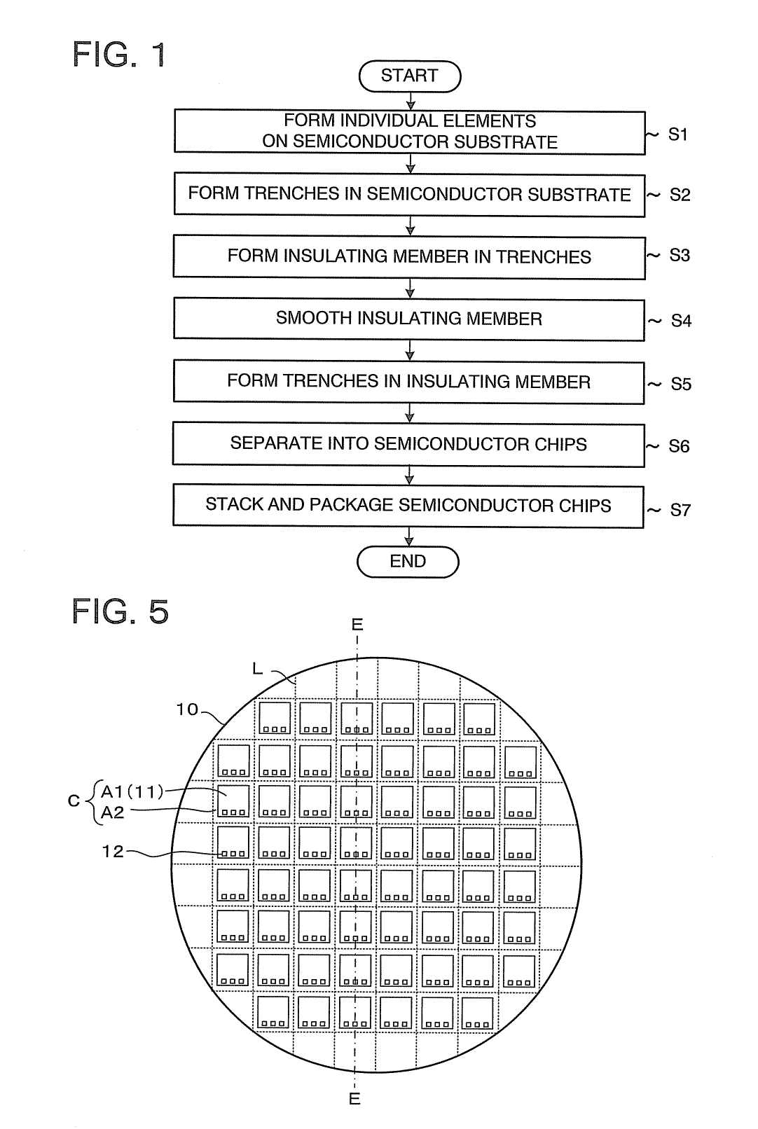

FIG. 1 is a flowchart representing an example of a manufacturing procedure of a semiconductor device according to the embodiment. The semiconductor device manufactured by the procedure of FIG. 1 is a chip stacked package (for example, a semiconductor memory) formed by stacking a plurality of semiconductor chips.

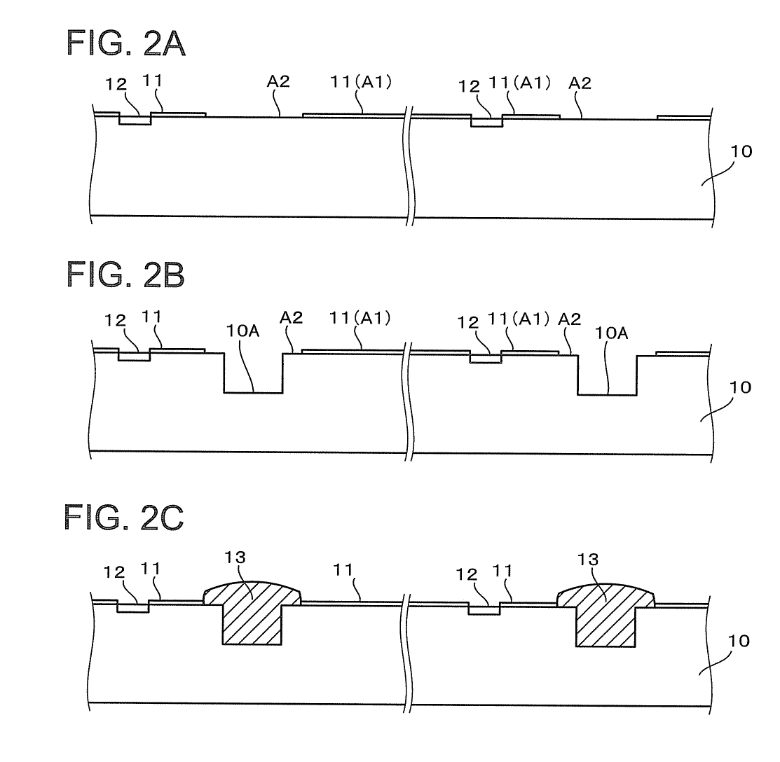

FIG. 2A to FIG. 2C, FIG. 3A to FIG. 3C, and FIG. 4A to FIG. 4C are cross-sectional views representing an example of the semiconductor device manufactured by the procedure of FIG. 1. Note that in FIG. 2A to FIG. 2C, FIG. 3A to FIG. 3C, and FIG. 4A to FIG. 4C, a portion of a semiconductor wafer is enlarged for clarifying characteristics of this embodiment.

### (1) Forming Individual Elements on a Semiconductor Substrate (Wafer) (Step S1)

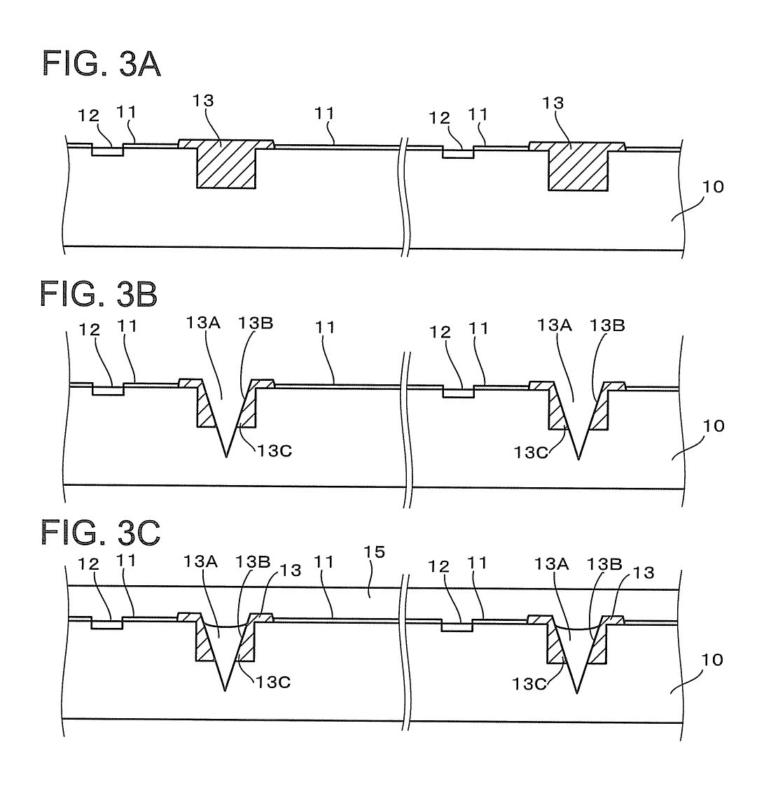

A plurality of individual elements corresponding respectively to a plurality of semiconductor chips C are formed on a semiconductor wafer 10 (FIG. 5 and FIG. 2A).

FIG. 5 is a top view representing the semiconductor wafer 10 on which the individual elements are formed. FIG. 2A is a cross-sectional view representing a state of the semiconductor wafer 10 shown in FIG. 5 cut along a line E-E. Note that the other cross-sectional views (FIG. 2B to FIG. 2C, FIG. 3A to FIG. 3C, and FIG. 4A to FIG. 4C) correspond to FIG. 2A.

Note that structures of the individual elements formed in the semiconductor wafer 10 are omitted in FIG. 2A for the sake of clarity in viewing. The same applies to the other cross-sectional views (FIG. 2B to FIG. 2C, FIG. 3A to FIG. 3C, and FIG. 4A to FIG. 4C).

As shown in FIG. 5, the semiconductor chips C on the semiconductor wafer 10 are sectioned by boundary lines L. However, these boundary lines L are virtual lines. A semiconductor chip C has a protection area (element separation area) A1 on which an insulating resin film 11 is formed and a non-protection area A2 on which the insulating resin film 11 is not formed. Within this element separation area A1, an individual element of each semiconductor chip C is formed and protected electrically by the insulating resin film 11. As already described, the individual elements are formed inside the semiconductor wafer 10, but structures thereof are omitted from illustration.

Electrode pads 12 for connecting the individual element to the outside (for example, other semiconductor chips C or substrates) is formed in the element separation area A1. The electrode pads 12 are formed from a good electric conductor such as copper. On the electrode pads 12, the insulating resin film 11 has openings to allow connection between the outside and the electrode pads 12.

### (2) Forming Trenches 10A in the Semiconductor Substrate (Wafer) (Step S2)

In the semiconductor wafer 10, trenches (element disconnection lines) 10A are formed along the boundary lines L (FIG. 2B). These trenches 10A are formed using a dicing blade or the like for example so as not to penetrate the semiconductor wafer 10 (first half-cut dicing).

### (3) Forming an Insulating Member 13 in the Trenches 10A (Step S3)

An insulating member 13 is formed in the trenches 10A. For example, an insulating resin is filled in the trenches 10A to form an insulating member (embedding resin) 13 formed of the insulating resin (FIG. 2C). For example, dispensing, ink-jetting, jet-dispensing, printing, or the like is used to inject or fill a liquid insulating resin material in the trenches 10A.

As the insulating resin, for example, a thermosetting resin such as a phenol resin, a melamine resin, a urea resin, and an epoxy resin can be used. After injecting or filling the insulating resin in the trenches 10A, the insulating resin of the insulating member 13 is cured by heating or the like in preparation to following steps S4, S5 (smoothing and forming the trenches 13A).

Incidentally, when using ink jetting, the diameter of a nozzle tip is set to a predetermined size, and the insulating resin is ejected toward the trenches 10A, to thereby form the insulating member 13. Further, when using printing, a mask corresponding to the shape and size of the trenches 10A and a formation pattern are prepared, and the insulating member 13 is formed by printing the insulating resin via this mask.

The insulating member 13 is formed for preventing wires connecting the semiconductor chip C and the outside from directly contacting and short circuiting with the main body of the semiconductor substrate 10. Specifically, side faces (and a portion of the upper face (non-protection area A2)) of the semiconductor chip C are covered with the insulating member 13, so as to electrically insulate wires disposed thereon from the semiconductor substrate 10.

Specifically, the insulating member 13 is formed so that the non-protection area A2 of the semiconductor wafer 10 is covered with the insulating member 13. As described later, wires are formed between the outside and the electrode pads 12 via the non-protection area A2. Incidentally, the insulating member 13 may be arranged not only on the non-protection area A2 but on the protection area A1.

### (4) Smoothing the Insulating Member 13 (Step S4)

An upper portion of the insulating member 13 is smoothed. The insulating member 13 has a projecting portion (elevated portion) above each trench 10A. This projecting portion is planarized (FIG. 3A). A blade, a grinding stone, a cutting tool, or the like can be used for this planarization.

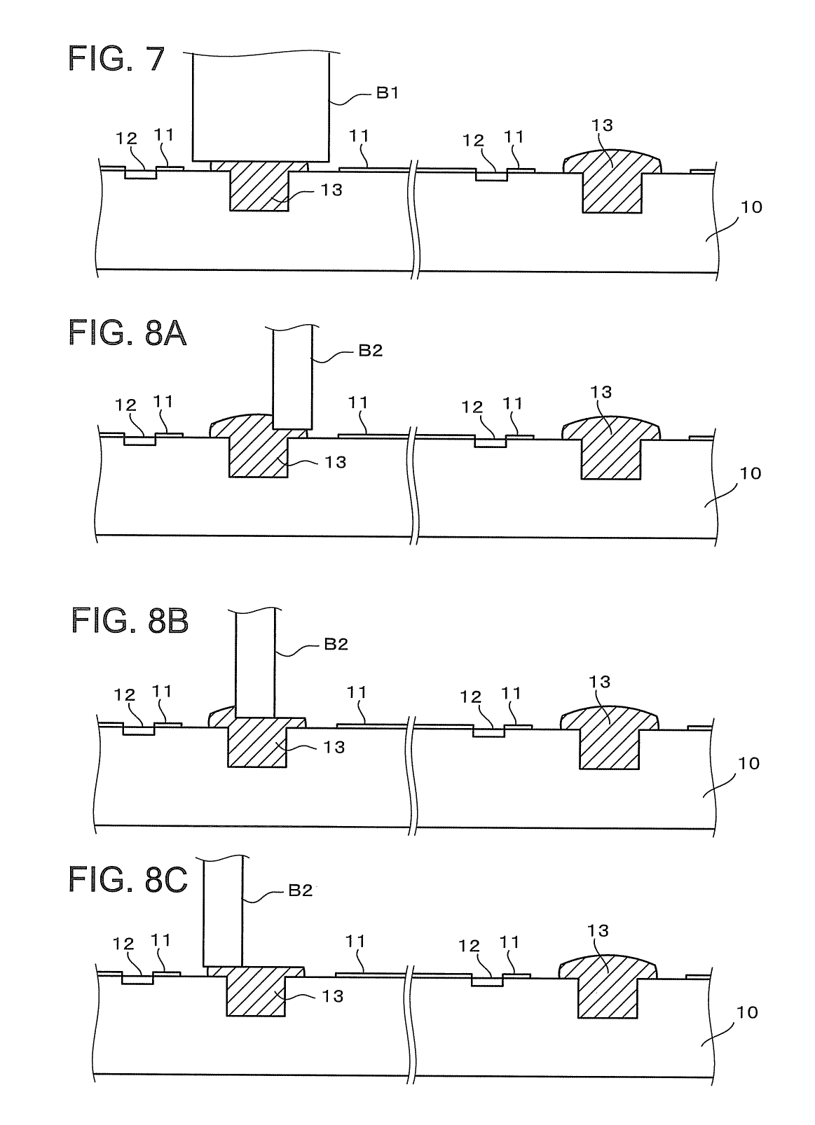

FIG. 7 is a view representing a state that a projecting portion of the insulating member 13 is smoothed using a blade B1. The blade B1 has a larger width than the width of the projecting portion of the insulating member 13. Thus using the blade B1 having a larger width than the width of the projecting portion of the insulating member 13, projecting portions of the insulating member 13 can be removed and smoothed in a lump.

FIG. 8A to FIG. 8C are views representing a state that a projecting portion of the insulating member 13 is smoothed using a blade B2. The blade B2 has a smaller width than the width of the projecting portion of the insulating member 13. Accordingly, while changing the position of the blade B2 from a right side to a left side, sweeping in a vertical direction on the view is performed three times on a right side of the projecting portion of the insulating member 13 (FIG. 8A), a middle of the projecting portion of the insulating member 13 (FIG. 8B), and a left side of the projecting portion of the insulating member 13 (FIG. 8C). Thus, the projecting portion of the insulating member 13 is removed and smoothed using the blade B2 having a smaller width than the width of the projecting portion of the insulating member 13 and by shifting its position.

To smooth the projecting portion of the insulating member 13 using a grinding stone, the semiconductor wafer 10 is brought into contact with the grinding stone arranged in parallel with the semiconductor wafer 10 while being rotated. As a result, a part of the projecting portion of the insulating member 13 is removed by the grinding stone.

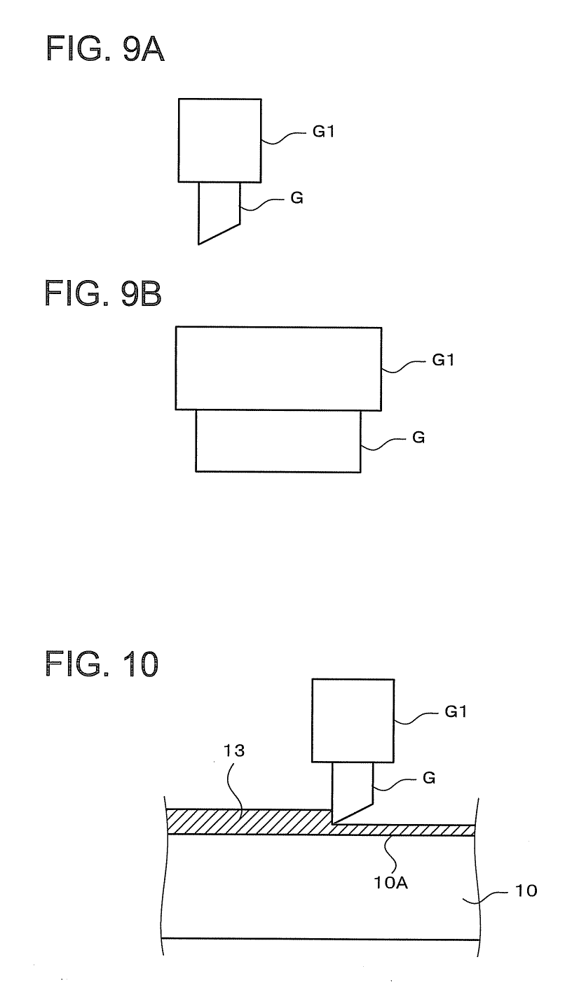

FIGS. 9A, 9B are a side view and a front view representing a cutting tool G. The cutting tool G is held by a holding tool G1. FIG. 10 is a view representing a state that the projecting portion of the insulating member 13 is smoothed using the cutting tool G. This FIG. 10 represents a state of the semiconductor wafer 10 cut along a trench 10A. As shown in FIG. 9A and FIG. 9B the cutting tool G has a rectangular front face and has a trapezoidal side face with an acute corner. That is, the cutting tool G has an acute tip portion.

To smooth the projecting portion of the insulating member 13 using the cutting tool G, the semiconductor wafer 10 is brought into contact with the cutting tool G arranged in parallel with the semiconductor wafer 10 while being rotated. As a result, a part of the projecting portion of the insulating member 13 is removed by the cutting tool G.

The width of the area to be smoothed can be approximately the same as the width of the trench 10A (element cutting line width). Alternatively, the width of the area to be smoothed may be made larger than the width of the trench 10A, so that the smoothing is performed further in the vicinity of the electrode pads 12.

In FIG. 3A, corresponding to the latter, the entire projecting portion of the insulating member 13 is smoothed.

On the other hand, the area to be smoothed may be a part of the projecting portion. Specifically, a residual portion (a remaining resin) is allowed to exist when removing (planarizing) the projecting portion of the insulating member 13. However, considering subsequent steps (wiring for example), the width of the residual portion is desired to be about 3 μm to 50 μm.

### (5) Forming the Trenches 13A in the Insulating Member 13 (Step S5)

The trenches 13A are formed in the insulating member (embedding resin) 13 (FIG. 3B). These trenches 13A are formed using a dicing blade or the like for example so as not to penetrate the semiconductor wafer 10 (second half-cut dicing).

Side faces of the trenches 13A are preferred to be slanted to a certain degree rather than being vertical. This is for forming, as described later, wires for electrical connection between stacked semiconductor chips C (or between semiconductor chips C and a substrate) on side faces of the insulating member 13 remaining after forming the trenches 13A.

In FIG. 3B, the trenches 13A are formed in a V shape. In this case, the remaining insulating member 13 has side faces 13B originating in the trenches 13A in a tapered shape, and the side faces 13B have a relatively small rising angle. As described above, the remaining insulating member 13 as it is forms an insulating layer on side faces of the semiconductor chip C. Accordingly, when the side faces 13B of the remaining insulating member 13 has a small rising angle, the insulating layer also has a small rising angle. Therefore, the insulating layer has good adhesion with, for example, the semiconductor chip located under this layer, and thus delamination can be suppressed.

Further, the side faces 13B of the remaining insulating member 13 in a tapered shape makes the entire remaining insulating member 13 be relatively thick. Therefore, the remaining insulating member 13 has edge portions 13C originating in the trenches 10A with a relatively large thickness of the semiconductor wafer 10. As described above, the remaining insulating member 13 as it is forms an insulating layer on side faces of the semiconductor chip. Thus, when the edge portions 13C, which originate in the trenches 10A of the semiconductor wafer 10, of the remaining insulating member 13 have a relatively large thickness, edge portions corresponding to the semiconductor chip of the insulating layer also have a relatively large thickness. Therefore, sufficient insulation can be secured in the edge portions where it is relatively difficult to secure insulation.

Here, the trenches 13A penetrate the insulating member 13. Consequently, bottoms (lower ends) of the trenches 13A are located lower than bottoms (lower ends) of the trenches 10A. In this structure, the insulating member 13 can be utilized effectively as an insulating layer on side faces of the semiconductor chip. That is, the entire thickness of the insulating member 13 can be used as an insulating layer by grinding a back face of the semiconductor wafer 10 to the bottoms of the trenches 10A in later grinding (step S6).

However, penetration of the trenches 13A through the insulating member 13 is not essential. The depth of the trenches 13A will suffice as long as the semiconductor wafer 10 is cut and separated into semiconductor chips in later grinding.

A blade of normal type or V-shaped type is used for forming the trenches 13A. The former blade has a cross section with a bottom which is straight in a horizontal direction, causing a formed trench 13A to have a bottom face along the horizontal direction. The latter blade has a cross section with a V-shaped bottom, causing a formed trench 13A to have a V-shaped side faces. In the example shown in FIG. 3B, the V-shaped type blade is used.

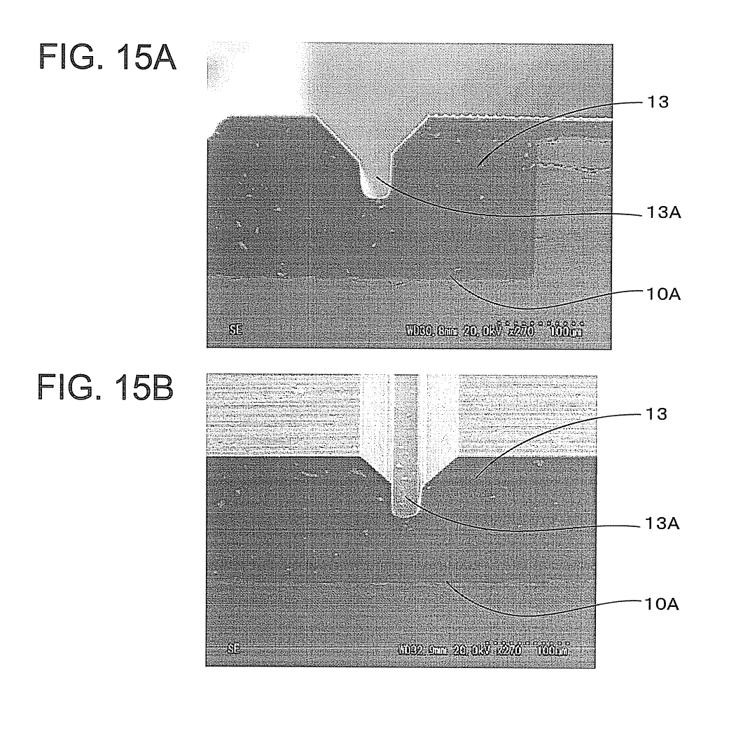

When forming the trenches 13A, a plurality of blades with different shapes can also be used. For example, the trenches 13A may be formed by a combination of a V-shaped type wide blade and a normal type narrow blade (see FIG. 15 described later). Thus using a plurality of blades with different shapes facilitates making the trenches 13A with appropriate shapes.

Further, the above-described smoothing and forming of the trenches 13A can also be performed with a same device (for example, a dicing device). Particularly, the smoothing and forming of the trenches 13A can be performed at once. For example, using the blade B2 having a smaller width than the width of the projecting portion of the insulating member 13, the blade B2 is swept several times while changing its height in steps. Thus, it is possible to perform smoothing and forming of the trenches 13A at once by sweeping while controlling the height of the blade.

(6) Separating into Semiconductor Chips C (Step S6)

The semiconductor wafer 10 is separated into semiconductor chips C. Specifically, a protection film (for example, an adhesive sheet of a BSG tape or the like) 15 is attached to the surface of the semiconductor wafer 10 (FIG. 3C). The back face of the semiconductor wafer 10 is ground thinly until the trenches 13A open (FIG. 4A). As a result, the semiconductor wafer 10 is divided into the semiconductor chips C (separation).

### (7) Stacking and Packaging the Semiconductor Chips C (Step S7)

An adhesive film 16 for stacking is adhered to the back face of the semiconductor wafer 10 and the protection film 15 is removed (FIG. 4B), and the adhesive film 16 for stacking is cut by each semiconductor chip C (FIG. 4C).

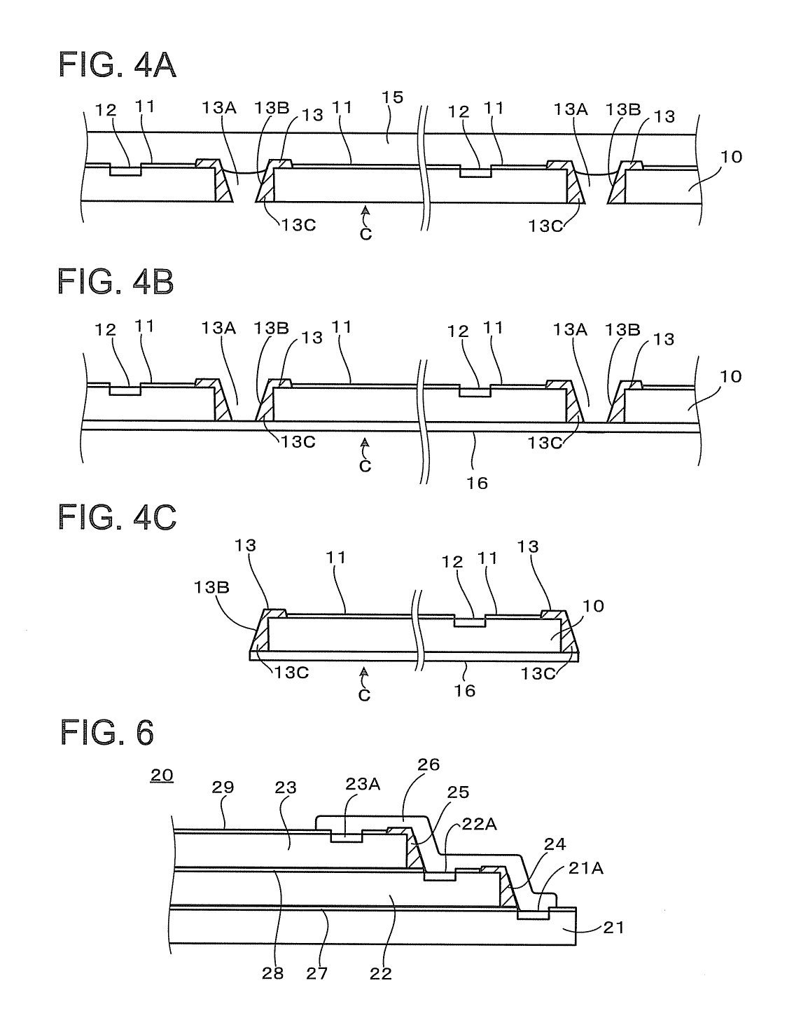

The semiconductor chips are stacked on a base such as a substrate, and wires (conductive members) are formed between the electrode pads 12, thereby completing a semiconductor device (FIG. 6). For example, a pattern (wiring) of a conductive member (for example, a conductive paste) can be formed using dispensing, ink jetting, jet dispensing, printing, or the like.

In a stacked type semiconductor package 20 shown in FIG. 6, semiconductor chips 22, 23 are stacked on a substrate 21 via adhesive layers 27, 28. Insulating layers 24, 25 corresponding to the remaining insulating member 13 are formed on both side faces of the semiconductor chips 22, 23.

Further, a wire 26 is formed so as to cover the insulating layers 24 and 25, electrically connecting an electrode pad 21A formed on the substrate 21 and electrode pads 22A and 23A formed on the semiconductor chips 22 and 23.

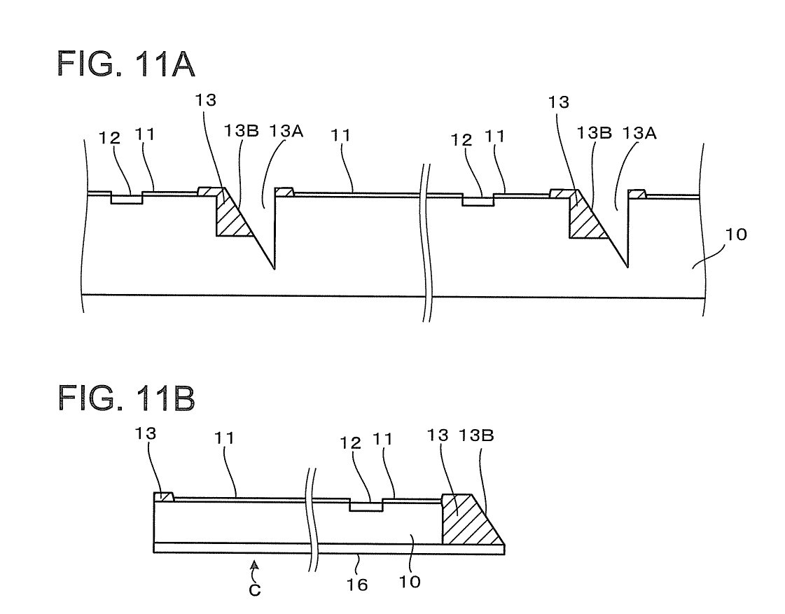

Incidentally, the trenches 13A may be formed in an arbitrary shape as necessary instead of the V shape shown in FIG. 3B. For example, as shown in FIG. 11A, the trenches 13A may be formed so that the insulating member 13 remains only on one side face of each trench 10A. In this case, the semiconductor chip C as shown in FIG. 11B is formed.

When the trenches 13A in a V shape as shown in FIG. 3B are formed, the insulating member 13 remains on the both side faces of the trenches 10A. Accordingly, insulating layers are formed on both side faces of the semiconductor chip C (FIG. 4C). When the trenches 13A are formed so that the insulating member 13 remains only on one side face of each trench 10A as shown in FIG. 11A, an insulating layer is formed on one of the side faces when the semiconductor chip is stacked (FIG. 11B).

In the former case, electrical connection can be made on the both side faces of the stacked semiconductor chip. On the other hand, in the latter case, electrical connection can only be made on one side face of the stacked semiconductor chip.

### EXAMPLE

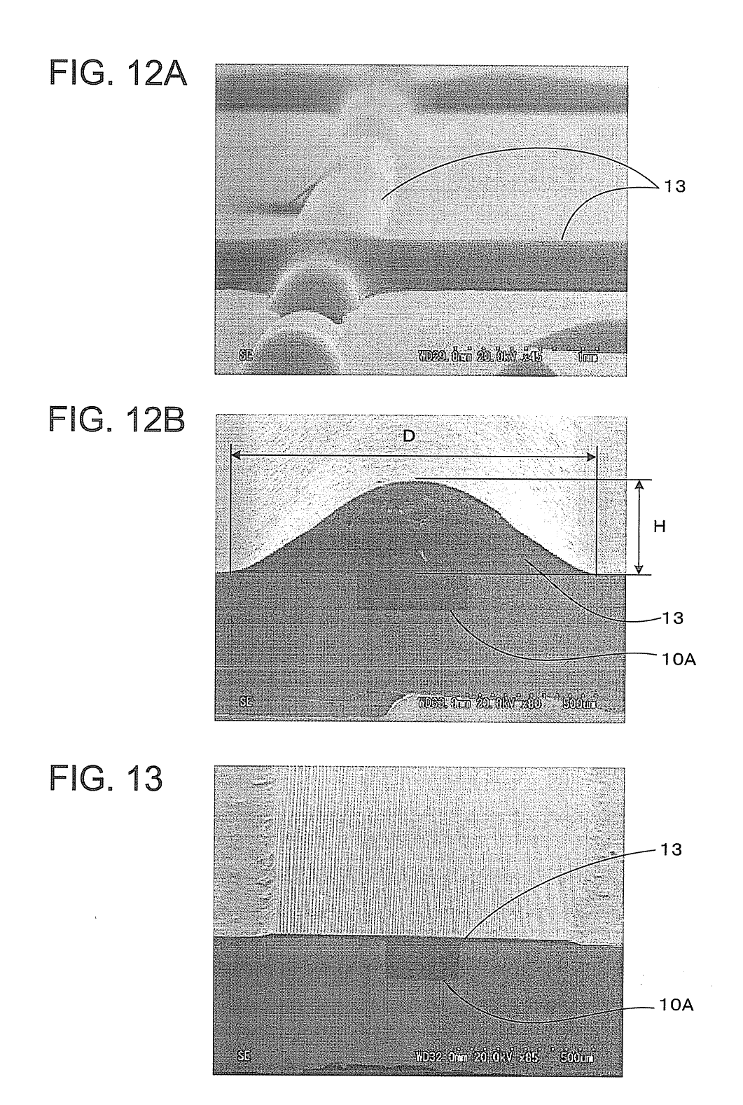

An example will be shown. FIG. 12A to FIG. 15B are electron micrographs representing a semiconductor device according to the example.

FIGS. 12A, 12B represent a state that the insulating member 13 is formed corresponding to FIG. 2C. It can be seen that the insulating member 13 has a projecting portion. In this example, the insulating member 13 has a width D and a height H of 1440 μm and 373 μm, respectively.

FIG. 13 represents a state that the insulating member 13 is smoothed corresponding to FIG. 3A. It can be seen that the insulating member 13 is smoothed.

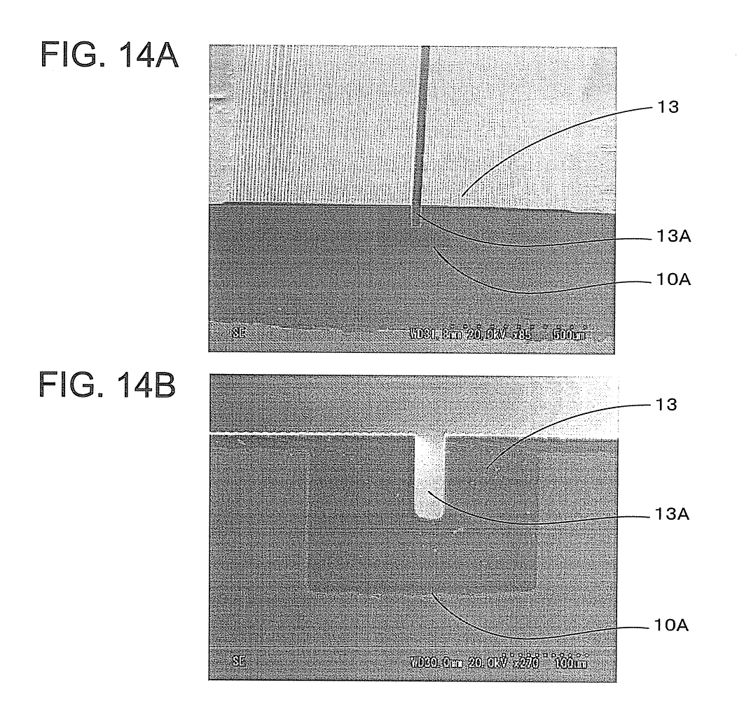

FIGS. 14A, 14B and FIGS. 15A, 15B represent a state that a trench 13A is formed in the insulating member 13 corresponding to FIG. 3B. It can be seen that the insulating member 13 is smoothed. The shape of the trench 13A differs between FIGS. 14A, 14B and FIGS. 15A, 15B, and the former and the latter have a cross section with a straight bottom and a cross section with a non-straight bottom, respectively. In the latter, the trench is formed using a blade having a cross section with a V-shaped bottom and a blade having a cross section with a straight bottom. However, a trench with such a shape may be formed by one blade.

As described above, in this embodiment, the insulating member 13 is formed and planarized in trenches of a semiconductor wafer in the vicinities of the electrode pads 12 when manufacturing a stacked semiconductor package using thin semiconductor chips C.

Consequently, this embodiment can provide the following advantages (1) and (2).

(1) Side faces of the semiconductor chip C are covered with the insulating member 13. Accordingly, short-circuit of the wires 26 can be prevented when electrically connecting the semiconductor chips C and the outside.

(2) Adhesion between the semiconductor substrate 10 and the protection film 15 is excellent due to the insulating member 13 being planarized. Accordingly, when grinding the back face of the semiconductor substrate 10, it is possible to prevent occurrence of an element crack due to mixing of bubbles in the protection film 15 and contamination by mixing of grinding water.

When bubbles enter between the semiconductor substrate 10 and the protection film 15, an element crack occurs as follows. Specifically, when the back face of the semiconductor substrate 10 is ground to thin the semiconductor substrate 10, it is possible that deflection occurs at a position where the bubbles exist and causes a crack. Particularly, when the semiconductor substrate 10 is ground thinly, the deflection becomes large and easily causes a crack.

When the element crack or contamination occurs in the semiconductor substrate 10, a defect (operation failure) may occur in a formed semiconductor device (chip stacked package). In this embodiment, planarizing the insulating member 13 enables to reduce defects of the semiconductor device due to poor adhesiveness between the semiconductor substrate 10 and the protection film 15.

While certain embodiments have been described, these embodiments have been presented by way of example, only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

In the above-described embodiment, the projecting portion of the insulating member 13 is removed and the upper part of the insulating member 13 becomes flat. Here, it is not necessary to remove the entire projecting portion. Reduction of the volume of the insulating member 13 provided in the trenches 10A enables to prevent occurrence of a crack or the like.

What is claimed is:

1. A manufacturing method of a semiconductor device, comprising:
forming in a semiconductor substrate having a first and a second main surface a plurality of first trenches in the first main surface;
forming in the first trenches an insulating member having an upper face located higher than the first main surface;
removing a part of a portion of the insulating member, the portion being located higher than the first main surface;
forming second trenches in the insulating member after the removing; and
attaching a protection film on the first main surface.

2. The manufacturing method of a semiconductor device according to claim 1,
wherein in the forming of the second trenches, the part of the semiconductor substrate is removed so that lower ends of the second trenches are located lower than the first trenches.

3. The manufacturing method of a semiconductor device according to claim 1,
wherein in the removing, the portion of the insulating member is removed so that an upper face of the insulating member becomes substantially flat.

4. The manufacturing method of a semiconductor device according to claim 1, further comprising:
polishing the second main surface of the semiconductor substrate and exposing lower ends of the first or second trenches to the second main surface; and
providing a conductive member on an upper face and side faces of the insulating member.

5. The manufacturing method of a semiconductor device according to claim 1,
wherein the forming of the insulating member comprises:
injecting or filling a liquid insulating resin material in the plurality of first trenches; and
curing the insulating resin material.

6. The manufacturing method of a semiconductor device according to claim 5,
wherein in the injecting or in the filling, dispensing, ink-jetting, jet-dispensing, or printing is used.

7. The manufacturing method of a semiconductor device according to claim 1,
wherein in the removing, a blade having a larger width than a width of the part is used.

8. The manufacturing method of a semiconductor device according to claim 1,
wherein in the removing, a blade having a smaller width than a width of the part is moved and used.

9. The manufacturing method of a semiconductor device according to claim 1,
wherein in the forming of the second trenches, a blade having a cross section with a straight or V-shaped bottom is used.

10. The manufacturing method of a semiconductor device according to claim 1,
wherein in the forming of the second trenches, a plurality of blades with different shapes from each other are used.

11. The manufacturing method of a semiconductor device according to claim 4,
wherein in the exposing, the semiconductor substrate is separated into a plurality of semiconductor chips.
